(19) United States
(12) Patent Application Publication
(10) Pub. No.: US 2008/0054270 A1
(43) Pub. Date: Mar. 6, 2008

(54) Semiconductor memory device and the production method

(76) Inventor: Yoshiyuki Suda, Tokyo (JP)

Correspondence Address: DITTHAVONG MORI & STEINER, P.C., 918 Prince St., Alexandria, VA, 22314, US

(21) Appl. No.: 11/725,009

(22) Filed: Mar. 16, 2007

(30) Foreign Application Priority Data
Sep. 5, 2006 (JP) 2006-239972

(51) Int. Cl. H01L 29/12; H01L 21/31

(52) U.S. Cl. 257/77; 438/761; 257/E29.068; 257/E21.24

(57) ABSTRACT

A semiconductor memory device that is configured with a Si substrate layer, a SiC layer and a Si oxide layer, including a structure in which the SiC layer is layered onto the Si substrate layer and the Si oxide layer is layered onto the SiC. Wherein, the Si oxide layer includes two or more layers whose compositional ratios of SiO₂ are different in a direction of layers, and a compositional ratio of SiO₂ in the. Si oxide layer that is distanced most from the SiC layer is more than other layers.

### CROSS REFERENCES TO RELATED APPLICATIONS

The present invention contains subject manner related to Japanese Patent Application JP2006-239972 filed in the Japanese Patent Office on Sep. 5, 2006 and the entire contents of which being incorporated herein by reference.

### BACKGROUND OF THE INVENTION

1. Field of the Invention

The present invention relates to a semiconductor memory device of two terminals that is configured with Si, SiC and Si oxide, and to the production method.

2. Description of the Related Art

Recently, a semiconductor memory device is being used as a storage device in various fields. A flash memory, RAM (Random Access Memory) and ROM (Read Only Memory) or the like are used as the semiconductor memory of the related art, and those are a three-terminal memory in which three control electrodes are necessary. Recently, along a request of expansion of storage volume of information, an appearance of a two-terminal memory controllable with two electrodes is being desired. The two-terminal memory reduces the number of electrodes in comparison with the three-terminal memory, thereby decreasing an occupied area per one memory in a circuit substrate. Therefore, the number of memories per a unit area in the circuit substrate can be increased and the volume of information per area, specifically a storage density of information, can be expanded. Consequently, the production of the storage device that can treat more volume of information becomes possible by a substrate of small area.

As two-terminal memory, Mr. Suda and others reported a memory that used SiC in the published non patent document: K. Takada, M. Fukumoto & Y. Suda, [Memory Function of a SiO₂/β-SiC/Si MIS Diode], Ext. Abs. 1999, International Conference on Solid State and Materials, p. 132-133(1999). In the memory, a SiC film is formed on N-type Si substrate and Si oxide is produced in the upper portion of the SiC film. Specifically, it is a structure having Si oxide/SiC/Si substrate, in order from the top. The upper portion of the SiC is heat-treated and oxidized at 1000° C., thereby removing the C by the invasion of oxygen O as CO or CO₂, and then the Si oxide is formed with combining residual Si with oxygen O. The SiC on the side of the Si substrate remains just as SiC without being oxidized.

FIG. 2 shows a model of a memory operation of the related art by a band diagram.

As for a Si oxide in a memory that used the above SiC, an oxidation temperature is low as 1000° C., so SiO₂ that is a perfect oxide and Si oxide SiOₓ (x<2) that is a non-perfect oxide coexist. Also, the oxide is formed through a process, in which C of SiC is removed, so Si having a dangling bond that does not bond to other atoms exists as crystalline defect if the temperature is low, and also this dangling bond emits electron, consequently it remains as Si⁺ that electrically charged with plus. Therefore, such donor-type defect exists in an area of the Si oxide and a boundary surface between the Si oxide and the SiC. Especially, much more donor-type defects exist in a boundary surface (or interface) between the Si oxide and the SiC (FIG. 2(1)).

In a case in which a plus voltage is applied onto a surface of Si oxide, the applied voltage is imposed mainly onto the Si oxide and SiC, because resistance of the Si substrate is low. However, a current hardly flows because the Si oxide becomes a barrier. Specifically, it becomes a condition of high resistance as a whole memory device. The condition where the resistance is high becomes an OFF state (see FIG. 2(2)).

A band gap of the Si is 1.1 eV (electron Volt) and a band gap of the SiC is 2.3 eV in case of a cubic crystalline structure. In a case in which the voltage is further increased, because there is a band gap difference between the SiC and the Si substrate, electrons are injected into the SiC side from the Si substrate when exceeding a certain voltage, then the electrons are captured by the Si⁺ which exists in many at the boundary surface between the Si oxide and the SiC and which is a donor-type defect. At that time, it becomes difficult to impose the voltage onto from the Si substrate to an area where the electrons are captured, and then the voltage is further imposed onto the Si oxide area where the captured quantity of electrons is small. Because of that, a strong electric field occurs at the Si oxide and electrons come to be tunneled through the Si oxide, and consequently the current flows. Therefore, it means that the resistance decreases as a whole memory device. The condition where the resistance is low is an ON state (see FIG. 2(3)).

The transition from the OFF state to the ON state corresponds to a read-in of “1” of information.

In a case in which a minus voltage is applied to the surface of Si oxide, when the memory device is the ON state, the voltage is imposed mainly onto the Si oxide because electrons are being captured in the Si⁺ of donor-type defect, and then continuously, electrons are tunneled through the Si oxide and the current flows (FIG. 2(4)). However, in the case in which the minus voltage is further applied to the surface of Si oxide, electrons that are captured are emitted and then the Si⁺remains, consequently electrons return to the Si substrate side. Therefore, again the voltage comes to be imposed onto both of the Si-Oxide and the SiC (FIG. 2(5)). Consequently, the electric field of the Si oxide becomes weak and then electrons become difficult to be tunneled through the Si-Oxide and the current hardly flows. Specifically, the resistance becomes the increase as a whole memory device and it becomes the OFF state (FIG. 2(6). The transition from the ON state to the OFF state corresponds to a deletion of information or a read-in of “0” of information.

Specifically, the memory operation is using the donor-type defects that are formed in the Si oxide. It becomes an ON state when capturing electrons in the Si⁺ of donor-type defect that is generated in the Si oxide and the boundary surface between the Si oxide and the SiC, and it becomes an OFF state when emitting electrons from the donor-type defects. Therefore, as the memory operation, the ON state is able to correspond to storage of logic “1” and the OFF state is able to correspond to storage of logic “0”.

If the voltage that is applied to the Si oxide is made big enough to the plus side, the OFF state can be changed to the ON state, and reversely, the ON state can be changed to the OFF state, if the voltage is made big enough to the minus side. Also, “0” (the OFF state) that is a storage value of the device or “1” (the ON state) can be read out by checking whether or not the current flows at a low voltage.

It should be noted that the oxidation of the SiC can form much more donor-type defects than the direct oxidation of the Si. It is because the removal of C and the formation of Si oxide can be easily realized by oxidizing SiC.

Also, because of the existence of the SiC, it changes to the case in which the voltage is imposed onto both of the SiC and the Si oxide, or the case in which the voltage is imposed onto only the Si oxide, by the existence or the non-existence of the captured electrons in the defects, and consequently it changes the easiness of the current flow, specifically the resistance of the memory device.

In this manner, the memory device that uses SiC is configured.

### SUMMARY OF THE INVENTION

In the memory device of the structure of a Si oxide/SiC/Si substrate of the related art, the SiC is oxidized with low temperature at 1000° C. Because of that, a lot of SiOₓ other than SiO₂ exists in the Si oxide. A ratio of SiOₓ in the Si oxide exceeds 10%, so the donor-type defects are widely distributed over the whole Si oxide and at the time when electrons are captured in these defects once, the phenomenon in which the electrons are not emitted from the Si occurs even if the voltage to the Si oxide side is made big enough to the minus. Because of that, if it becomes the ON state once after capturing the electrons, the phenomenon in which it does not return to the ON state occurs, and consequently it does not operate as the memory. In order to use it as the memory, the structure by which the capture and emission of the electrons in the Si⁺ become easy is necessary because the repetitional operation of the ON and OFF is necessary more than 10 to the power of 5 (or 10⁵).

In view of the above, the present invention is to provide a semiconductor device that can further improve the number of times of the repetitional operation of a memory than ones of the related art in a structure of Si oxide/SiC/Si substrate.

According to a first invention, a semiconductor memory device that is configured with a Si substrate layer, SiC layer and a Si oxide layer includes a structure in which the SiC layer is layered onto the Si substrate layer and the Si oxide layer is layered onto the SiC, wherein the Si oxide layer includes two or more layers whose compositional ratios of SiO₂ are different, in a direction of layers, and a compositional ratio of SiO₂ in the Si oxide layer that is distanced most from the SiC layer is more than other layers.

A second invention is the semiconductor memory device according to the first invention, wherein the Si oxide layer is formed by heat-treating and oxidizing the SiC layer.

A third invention is the semiconductor memory device according to the first or second invention, wherein the Si oxide layer includes: a first Si oxide layer that is formed by heat-treating and oxidizing the SiC layer at an oxidizing temperature of equal to or more than 1100° C.; and a second Si oxide layer that is formed by heat-treating and oxidizing the SiC layer at an oxidizing temperature of less than 1100° C., after formation of the first Si oxide layer.

A fourth invention is the semiconductor memory device according to the first, second or third invention, wherein the first Si oxide layer which is distanced most from the SiC and whose compositional ratio of SiO₂ is equal to or more than 90% in whole.

A fifth invention is the semiconductor memory device according to the first invention, wherein the Si-Oxide layer is formed by a deposition by an oxidation reaction in a mixed gas atmosphere.

A sixth invention is the semiconductor memory device according to the first invention, wherein the Si substrate layer is N-type semiconductor.

A seventh invention is a production method of a semiconductor memory device that is configured with a Si substrate layer, SiC layer and a Si oxide layer, includes the steps of: layering the SiC layer onto the Si substrate layer; and layering the Si oxide layer onto said SiC. Wherein, the Si oxide layer includes two or more layers whose compositional ratios of SiO₂ are different, in a direction of layers, and a compositional ratio of SiO₂ in the Si oxide layer that is distanced most from the SiC layer is more than other layers.

An eighth invention is the production method of a semiconductor memory device according to the seventh invention, wherein the Si oxide layer is formed by a deposition by an oxidation reaction in a mixed gas atmosphere.

According to the present invention, in a semiconductor memory device where a Si substrate layer, SiC layer and a Si oxide layer are layered in order, the Si oxide layer includes two or more layers that are the first Si oxide layer in which the compositional ratio of the SiO₂ is big and the second Si oxide layer in which the compositional ratio of the SiO₂ is small, in the direction of layers. Therefore, the first Si oxide layer functions as the ideal tunnel layer because electrons are not captured in the first Si oxide layer having few defects. Because the capture or emission of electrons can be performed effectively in the second Si oxide layer, the transition to the ON/OFF of the memory operation that was difficult heretofore becomes easy and the number of times of the repetitional operation is improved.

### BRIEF DESCRIPTION OF THE DRAWINGS

FIG. 1 is a graph that measured an active characteristic of the number of times of a memory operation of a semiconductor memory device in a structure of the related art;

FIG. 2 shows a model of a memory operation in a band diagram of the related art;

FIG. 3 is a structural diagram of a semiconductor memory device according to an exemplified embodiment of the present invention;

FIG. 4 is a flow chart that shows a production method of a semiconductor memory device according to an exemplified embodiment of the present invention;

FIG. 5 is a graph that shows a rate of content of SiO₂ and SiOₓ in the case in which a SiC is heat-treated and oxidized at 1200° C.;

FIG. 6 is a graph that shows a rate of content of SiO₂ and SiOₓ in the case in which a SiC is heat-treated and oxidized at 1000° C;

FIG. 7 is a structural diagram of a semiconductor memory device of mesa-type according to an exemplified embodiment of the present invention; and

FIG. 8 is a graph that measured an active characteristic of the number of times of a memory operation of a semiconductor memory device according to an exemplified embodiment of the present invention.

### DESCRIPTION OF THE PREFERRED EMBODIMENTS

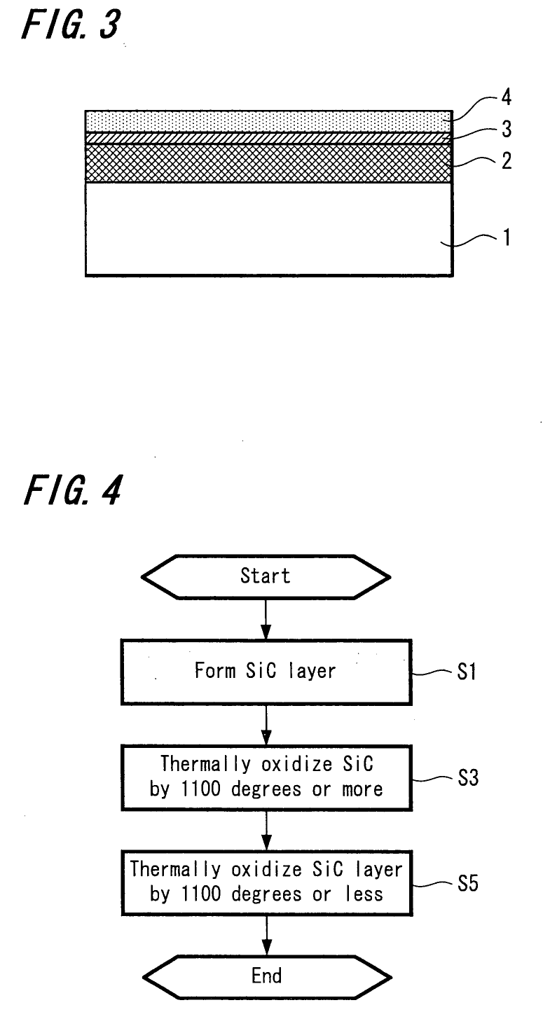

FIG. 3 is a structural diagram of a semiconductor memory according to an exemplified embodiment of the present invention. The numeral “1” indicates a Si substrate layer, the numeral “2” indicates a SiC layer, the numeral “3” indicates a second Si oxide layer and the numeral “4” indicates a first Si oxide layer.

The Si substrate layer 1 uses a Si (111) substrate that is doped to N-type. It is because the memory operation can be caused effectively by using the Si substrate of N-type whose electron density is high. Also, the quantity of defects of Si⁺ is controlled in the Si oxide and a boundary surface between the Si oxide and the SiC, therefore the SiC, itself that is formed on the Si substrate 1, is desired to be few defects and higher crystalline structure. In a case in which the surface direction of the substrate is a (111) surface, the high crystalline SiC film can be made.

Hereinafter, the production method of the semiconductor memory is explained by using a flow chart of FIG. 4.

The SiC layer 2 is formed on the Si (111) substrate 1 that is doped to N-type by CVD (Chemical Vapor Deposition) method (Step S1). The SiC layer 2 may be either one that is doped or one that is not doped. The SiC layer 2 that is doped to P-type may be formed on the Si substrate layer 1 that is doped to N-type.

Next, the oxygen is introduced to a heat-treated oxidation apparatus and the SiC is heat-treated and oxidized at equal to or more than 1100° C. in the oxidation atmosphere. Thus, the first Si oxide layer 4 is formed on the upper portion of the SiC layer 2 (Step S3).

Thickness of the first Si oxide layer may be in a range of 2 to 20 nm.

As for the first Si oxide layer 4, because the SiC is heat-treated and oxidized with high temperature, rate of content of SiO₂ can be made equal to or more than 90%. FIG. 5 shows the rate of content of the Si oxide in the depth direction to the SiC from the surface of the Si oxide, in the case in which the heat-treated oxidation is applied to the SiC at 1200° C. From FIG. 5, the rate of content of the SiO₂ that is a perfect oxide is about 90% in the areas from the surface of the Si oxide to near the boundary surface with the SiC. On the other hand, the rate of content of the SiOₓ that is an imperfect oxide is about 10% at the surface of Si oxide, and is only about 30% even near the boundary surface with the SiC.

Accordingly, it is conceivable that the first Si oxide layer 4 is configured with almost perfect oxide SiO₂.

Next, lowering the oxidation temperature to less than 1100° C., and the SiC is heat-treated and oxidized. Thus, the second Si oxide layer 3 is formed in between the SiC layer 2 and the first Si oxide layer 4 (Step S5).

Thickness of the second Si oxide layer 3 may be equal to or less than 10 nm.

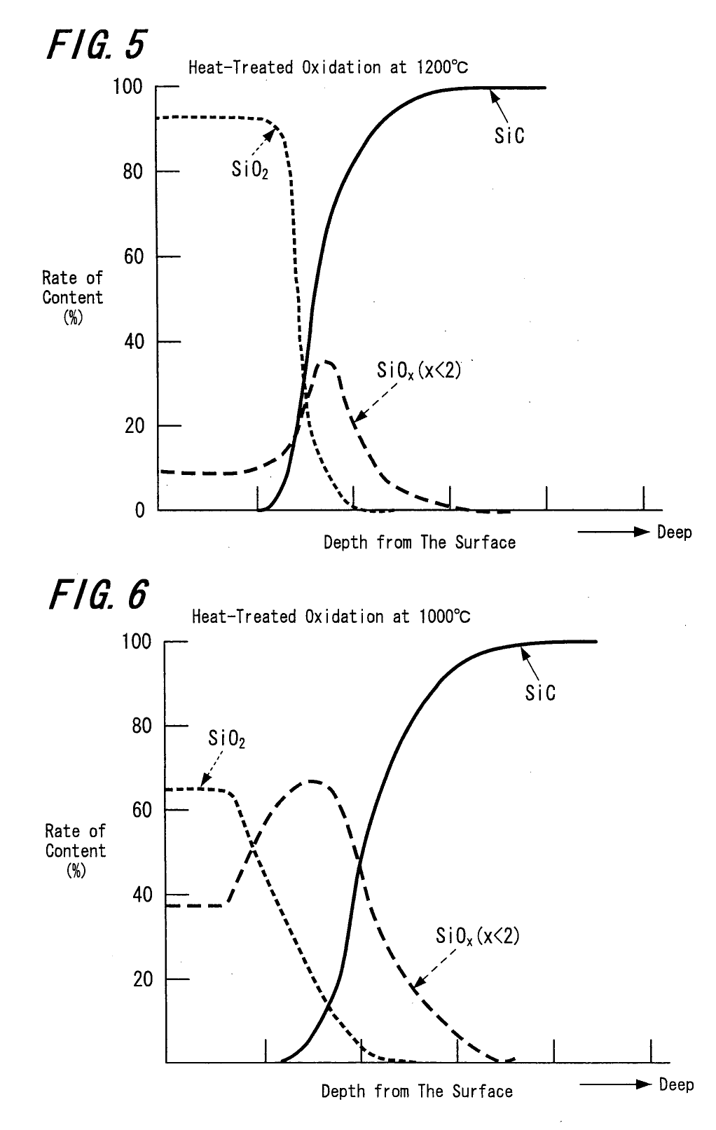

As for the second Si oxide layer 3, because the SiC is heat-treated and oxidized by a lower temperature than the first Si oxide layer 4, a ratio of the imperfect oxide SiOₓ is higher than ones of the first Si oxide layer 4. FIG. 6 shows the rate of content of the Si oxide in the depth direction to the SiC from the surface of the Si oxide, in the case in which the heat-treated oxidation is applied to the SiC at 1000° C. From FIG. 6, the rate of content of the SiO₂ of perfect oxide is about 65% at the surface of the Si oxide, and it is less than the case in which the heat-treated oxidation is applied at 1200° C, and on the other hand, the rate of content of the SiOₓ that is an imperfect oxide is about 35% at the surface, and is about 65% at the vicinity of the boundary surface with the SiC and, those are high.

Accordingly, it is conceivable that the second Si oxide layer 3 is configured with the oxide in which the imperfect oxide SiOₓ coexists.

It should be noted that a Si (100) substrate may be used as the Si substrate layer 1. Also, the heat-treatment may be performed timely in the inactive atmosphere such as an Ar after the formation of SiC or the formation of Si oxide layer.

Also, the first and second Si-Oxides may be formed by using a mixed gas of SiH₄ and N₂O by the CVD method by a deposition method by which Si oxide layer is deposited on SiC. After forming the second Si oxide layer by heat-treating and oxidizing the SiC, the first Si oxide layer may be formed by the deposition method. Also, the second and first Si oxides may be formed by the deposition method.

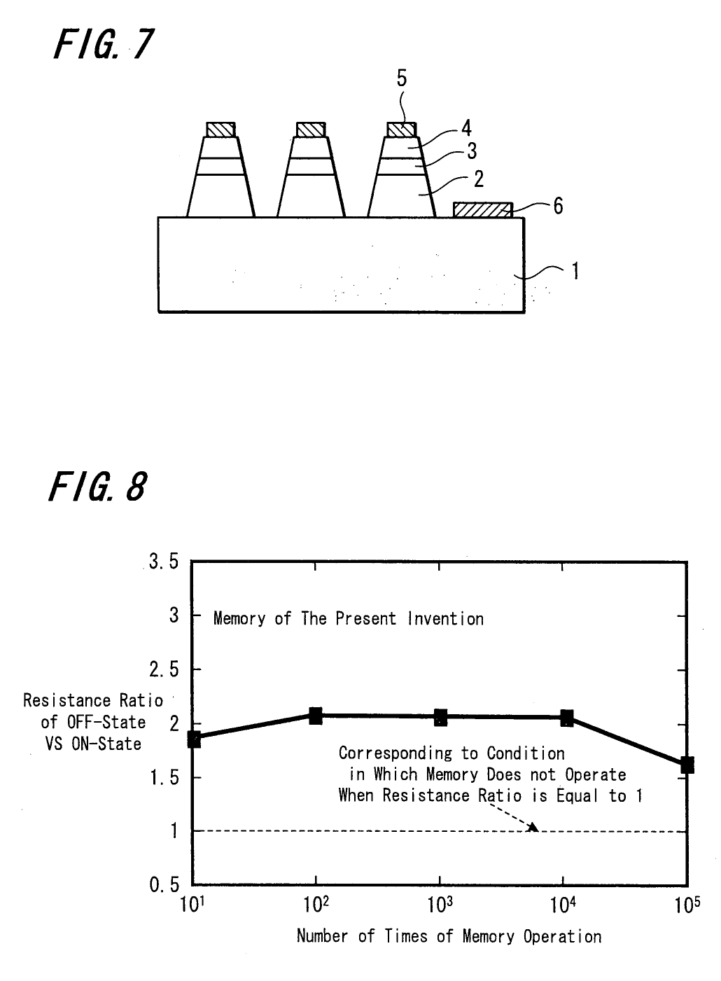

For the integration of the memory device, as is shown in FIG. 7, the first Si oxide layer 4, the second Si oxide layer 3 and the SiC layer 2 are etched to a mesa-type, and electrodes 5, 6 are formed onto the upper portion of first Si oxide layer and the Si substrate 1, respectively. Au, Pt, Ni, Al or the like may be used to the electrodes. Three-dimensional wirings may be made on the upper portion of many mesa-type memory devices, and one memory may be able to be selected electrically.

Hereinafter, it will be explained with respect to an exemplified embodiment of the present invention.

The SiC layer 2 was formed with epitaxicial growth to 400 angstroms by the CVD method on the Si (0.1 to 0.5 Ohm-cm, (100)) substrate layer 1 that was doped to N-type. Next, the oxygen was introduced to the heat-treated oxidation apparatus and three minutes oxidation was carried out at 1200° C. in the oxidation atmosphere and a first Si oxide layer 4 was formed. Thickness of the first Si oxide layer 4 was 12 nm.

Next, the oxidation temperature was lowered to 1000° C. and five minutes oxidation was carried out, and a second Si oxide layer 3 was formed. Thickness of the second Si oxide layer 3 was 2 nm.

Next, the first Si oxide layer 4, the second Si oxide layer 3 and the SiC layer 2 were etched to a mesa-type, and the Au electrode 5 was formed on the upper portion of the first Si oxide layer and the Al electrode 6 was formed on the Si substrate. After that, 3-dimensional wirings were formed on the upper portion of the mesa-type and an integrated type memory device was configured.

From the result of analysis by the X-ray photoelectron spectroscopic method, the first Si oxide layer 4 contained SiO₂ of a range of 95% to 100%, and the SiO₂ of the second Si oxide layer 3 was a range of 50% to 89%.

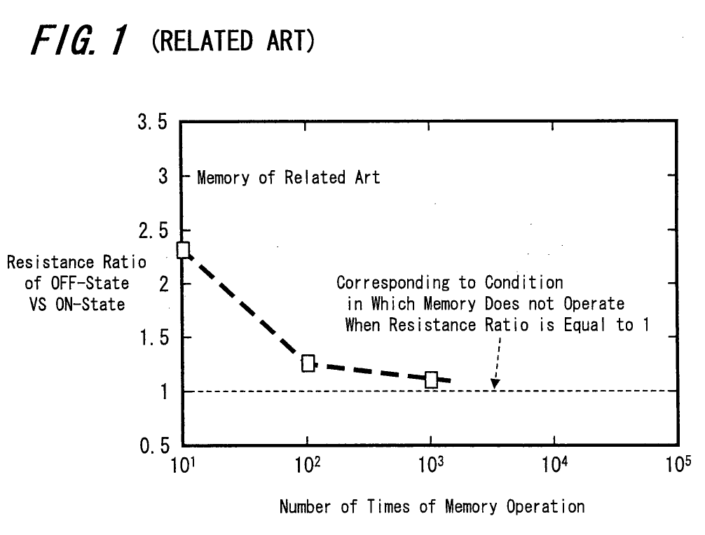

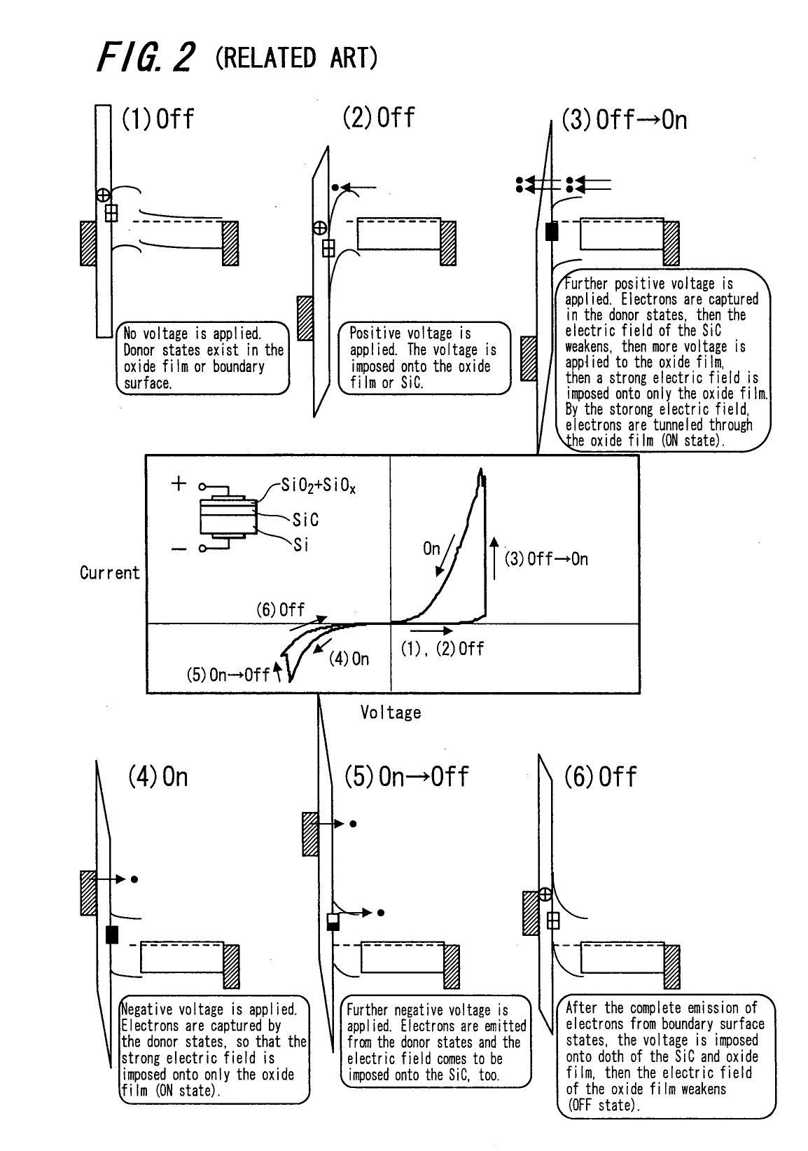

FIG. 1 is a graph that measured an active characteristic of the number of times of memory operation of a semiconductor memory device in a structure of the related art, and FIG. 8 is a graph that shows the measured result of the number of times of the memory operation in the semiconductor memory device of the above exemplified embodiment according to the present invention. It should be noted that, the vertical axis in FIG. 1 and FIG. 8 is the resistance ratio of the OFF state versus the ON state of the memory, and specifically, it shows how much current can not flow easily in the OFF state in comparison with the ON state. In case of the resistance ratio=1, the current does not change among the ON state and the OFF state, thereby corresponding to the condition in which it does not operate as the memory.

In this exemplified embodiment, the repetitional characteristic is improved more than 1000 times in comparison with the case in which the Si oxide layer of related art that is heat-treated and oxidized at 1000° C. is only one layer. Also, in the case in which the number of times of the memory operation exceeds 1000 times in the related art, the resistance ratio approaches 1, but even in the case in which the number of times of the memory operation is 10 to the power of 5 (or 10⁵) times, in this exemplified embodiment, the resistance ratio is more than 1.5 and the stable memory operation can be carried out.

Also, the defective area where electrons are captured is restricted to the extremely narrow range of 2 nm that is the thickness of the Si oxide layer, so the captured electrons are emitted easily by applying the voltage, and consequently the number of times of the repetition of the ON (that corresponds to the read-in of information “1”) and OFF (that corresponds to the deletion of information or the read-in of information “0”) reached 10 to the power of 5 (or 10⁵).

As is mentioned above, according to the exemplified embodiment of the present invention, as for a semiconductor memory device that is configured with a Si oxide layer, SiC layer and an N-type Si substrate layer, a structure of two or more Si oxide layer that are configured with: the first Si-Oxide layer which is almost the perfect oxide that includes SiO₂ whose ratio is more than 90%; and the second Si oxide layer which includes many defects and in which the ratio of the SiO₂ is less than the first Si oxide, is made as the Si oxide layer. Accordingly, the first Si oxide layer which includes few defects acts as the layer where the tunneling of electrons is performed effectively and the second Si oxide layer which includes many defects acts as the layer where the capture or emission of electrons is performed effectively, and consequently each can share the function in the memory operation. More specifically, because the defects can be formed in only the second Si oxide layer, there is nothing that disperses the defects all over the Si oxide and exists, like the related art.

Also, the second Si oxide layer can be formed extremely thinly without depending on the thickness of the first oxide layer. Thus, because the second Si oxide layer can emit electrons easily by applying the voltage, the transition to the OFF from the ON that was difficult heretofore becomes easy and the number of times of the repetitional operation is improved.

Also, in the case in which the SiC is heat-treated and oxidized in the oxygen atmosphere, the ratio of SiO₂ decreases to less than 90% if the oxidation temperature is less than 1100° C., but the ratio of SiO₂ increases to equal to or more than 90% if the oxidation temperature is equal to or more than 1100° C. Specifically, the perfection of Si oxide or the amount of defects can be controlled by the oxidation temperature of SiC. Therefore, the second Si oxide layer only or both of first and second Si oxide layers can be formed by controlling the oxidation temperature of SiC. By means of the heat-treated oxidation of the SiC, in the case in which two layers of first and second Si oxide layers are formed, because the oxidation goes to inside the layer from the surface, if the heat-treated oxidation is carried out by the high temperature at first and the heat-treated oxidation is carried out by the lower temperature at next, the first Si oxide layer that includes many SiO₂ is formed near the surface and also the second Si oxide layer that includes few SiO₂ is formed under that layer.

As described above, the exemplified embodiments of the present invention were explained with reference to the drawings, but it is apparent that the concrete configuration is not limited to the exemplified embodiment, and for example, a Si₃N₄ may be formed instead of the first Si oxide layer.

Having described preferred embodiments of the invention with reference to the accompanying drawings, it is to be understood that the invention is not limited to those precise embodiments and that various changes and modifications could be effected therein by one skilled in the art without departing from the spirit or scope of the invention as defined in the appended claims.

1. A semiconductor memory device that is configured with Si substrate layer, a SiC layer and a Si oxide layer, comprising:
a structure in which said SiC layer is layered onto said Si substrate layer and said Si oxide layer is layered onto said SiC, wherein said Si oxide layer includes:
two or more layers whose compositional ratios of SiO₂ are different, in a direction of layers; and
a compositional ratio of SiO₂ in said Si oxide layer that is distanced most from said SiC layer is more than other layers.

2. The semiconductor memory device according to claim 1, wherein said Si oxide layer is formed by heat-treating and oxidizing said SiC layer.

3. The semiconductor memory device according to claim 1, wherein said Si oxide layer, includes:
a first Si oxide layer that is formed by heat-treating and oxidizing said SiC layer at an oxidizing temperature of equal to or more than 1100° C.; and
a second Si oxide layer that is formed by heat-treating and oxidizing said SiC layer at an oxidizing temperature of less than 1100° C., after formation of said first Si oxide layer.

4. The semiconductor memory device according to claim 1, wherein said first Si oxide layer which is distanced most from said SiC and whose compositional ratio of SiO₂ is equal to or more than 90% in whole.

5. The semiconductor memory device according to claim 1, wherein said Si oxide layer is formed by a deposition by an oxidation reaction in a mixed gas atmosphere.

6. The semiconductor memory device according to claim 1, wherein said Si substrate layer is N-type semiconductor.

7. A production method of a semiconductor memory device that is configured with a Si substrate layer, SiC layer and a Si oxide layer, comprising the steps of:
layering said SiC layer onto said Si substrate layer; and
layering said Si oxide layer onto said SiC, wherein
said Si oxide layer includes two or more layers whose compositional ratios of SiO₂ are different, in a direction of layers; and
a compositional ratio of SiO₂ in said Si oxide layer that is distanced most from said SiC layer is more than other layers.

8. The semiconductor memory device according to claim 7, wherein said Si oxide layer is formed by a deposition by an oxidation reaction in a mixed gas atmosphere.
